(19) United States
(12) Patent Application Publication
(10) Pub. No.: US 2026/0163579 A1
(43) Pub. Date: Jun. 11, 2026

(54) ELECTRONIC DEVICE AND OFFSET CALIBRATION METHOD

(71) Applicant: NUVOTON TECHNOLOGY CORPORATION, HSINCHU CITY (TW)

(72) Inventor: Cheng-Chih WANG, Zhubei City (TW)

(21) Appl. No.: 19/408,942

(22) Filed: Dec. 4, 2025

(30) Foreign Application Priority Data
Dec. 10, 2024 (TW) 113147864

(51) Int. Cl. H03M 1/10

(52) U.S. Cl. CPC H03M 1/1009

(57) ABSTRACT

An electronic device includes an offset calibration module, an analog-to-digital converter module, a host, and an operational amplifier. The offset calibration module is configured to measure an operating voltage and a temperature and to determine whether it stores offset error information associated with the operating voltage and temperature. The operational amplifier has a negative input electrically connected to the offset calibration module, a positive input electrically connected to the analog-to-digital converter module, and an output electrically connected to the host. When the offset error information is stored, the offset calibration module outputs the offset error information to the operational amplifier, and the analog-to-digital converter module performs a normal analog-to-digital conversion based on a trigger signal to output a raw value to the operational amplifier. The operational amplifier then outputs a result value to the host.

### CROSS-REFERENCE TO RELATED APPLICATION

This application claims the priority benefit of Taiwan application serial no. 113147864, filed Dec. 10, 2024, the full disclosure of which is incorporated herein by reference.

### BACKGROUND

### Technical Field

The present disclosure relates to signal processing technology, and more particularly to an electronic device and an offset calibration method.

### Description of Related Art

Analog-to-digital converters (ADCs) can convert analog signals (e.g., analog voltages) into digital signals/forms, and are widely used in various electronic devices and systems, including medical equipment, audio systems, testing and measurement equipment, communication systems, and imaging and video systems.

FIG. 1 is a block diagram of an analog-to-digital converter module. Due to process variation or environmental influences, an additional offset voltage may occur between the positive and negative input terminals (i.e., AlN+ and AlN−) of the analog-to-digital converter module (hereinafter referred to as the ADC module) 10. This offset affects the accuracy of the system and causes output value deviation errors in the ADC module 10. To solve this problem, offset error calibration methods are commonly used. Two commonly used calibration methods are briefly introduced below.

FIG. 2 is a block diagram of an offset calibration system. In this method, the positive and negative input terminals of the ADC module 20 (i.e., AlN+ and AlN−) are first connected to a common-mode voltage terminal AlNCOM, such that the output of the ADC module 20 equals the offset value (V_{OS}). This offset value V_{OS} can be stored (e.g., in an offset error register). Then, the positive and negative input terminals of the ADC module 20 are restored to normal signal input mode (as shown in FIG. 1), and the output value of the ADC module 20 is subtracted by the offset value V_{OS} to obtain a corrected (non-offset) value. However, although this method can remove the offset error, it requires a common-mode voltage source and additional calibration time, which may affect system operation efficiency.

FIG. 3 is a block diagram of an offset calibration system. In this method, a chopper mode is applied via a control signal CHOP to eliminate offset errors, so that the output value of the ADC module 30 becomes a non-offset value. This method does not require an additional common-mode voltage source. However, the chopper mode causes the data rate to drop to half of its original rate and increases power consumption of the system.

Since offset error varies with process, voltage, and temperature (PVT), fluctuations in voltage and temperature in actual applications are inevitable. Therefore, how to effectively calibrate the offset error of the ADC module remains an issue worth addressing.

### SUMMARY

To address the problems described above, this disclosure provides an electronic device and a method for offset calibration.

The electronic device includes an offset calibration module, an analog-to-digital converter module, a host, and an operational amplifier. The offset calibration module is configured to measure an operating voltage and a temperature, and to determine whether the offset calibration module stores offset error information associated with the operating voltage and the temperature. The host is electrically connected to the offset calibration module and the analog-to-digital converter module and is configured to receive a status signal from the offset calibration module. The operational amplifier has a negative input terminal electrically connected to the offset calibration module, a positive input terminal electrically connected to the analog-to-digital converter module, and an output terminal electrically connected to the host. When the offset calibration module stores the offset error information, the offset calibration module outputs the offset error information to the operational amplifier. The analog-to-digital converter module, in response to a trigger signal, performs a normal analog-to-digital conversion to output a raw value to the operational amplifier, such that the operational amplifier outputs a result value to the host.

The present disclosure further provides an offset calibration method. The method includes measuring an operating voltage and a temperature. The method further includes determining whether the offset calibration module stores offset error information associated with the operating voltage and the temperature. When the offset calibration module stores the offset error information, the method includes outputting the offset error information from the offset calibration module, performing a normal analog-to-digital conversion by the ADC module to obtain a raw value, and subtracting the offset error information from the raw value to generate a result value. When the offset calibration module does not store the offset error information, the method includes performing an offset error calibration procedure by the ADC module to obtain the offset error information and storing the offset error information in the offset calibration module.

Accordingly, the disclosed electronic device and offset calibration method can efficiently correct offset errors in the ADC module and adapt to variations in voltage and temperature conditions.

### BRIEF DESCRIPTION OF THE DRAWINGS

Each of the drawings is briefly described as follows to enable those skilled in the art to better understand the present disclosure. The drawings form a part of the description of the disclosure.

FIG. 1 is a block diagram of an analog-to-digital converter module.

FIG. 2 is a block diagram of an offset calibration system.

FIG. 3 is a block diagram of another offset calibration system.

FIG. 4 is a block diagram of an electronic device according to an embodiment of the present disclosure.

FIG. 5 is a block diagram of an offset calibration module according to an embodiment of the present disclosure.

FIG. 6 is a flow diagram illustrating an offset calibration method according to an embodiment of the present disclosure.

FIG. 7 is a flow diagram illustrating another offset calibration method according to an embodiment of the present disclosure.

FIG. 8 is a flow diagram illustrating yet another offset calibration method according to an embodiment of the present disclosure.

### DETAILED DESCRIPTION

The present disclosure provides an electronic device and an offset calibration method to solve the problems described in the background. In order to make the features and advantages of the present disclosure more apparent and easier to understand, specific embodiments of the present invention will be described in detail below with reference to the drawings. The following descriptions contain specific information related to exemplary embodiments of the present disclosure. The drawings and the associated detailed descriptions in the present disclosure are for exemplary embodiments only. However, the present disclosure is not limited to these exemplary embodiments. Other modifications and implementations of the present disclosure will be apparent to those skilled in the art. Unless otherwise stated, the same or corresponding elements in the drawings may be denoted by the same or corresponding reference numerals. In addition, the drawings and illustrations in the present disclosure are generally not drawn to scale and are not intended to reflect actual relative sizes.

The following disclosure provides various embodiments or examples to implement different aspects of the present application. For the sake of clarity, the following disclosure describes specific examples of components and their arrangements. Of course, these specific examples are not intended to be limiting. For example, if an embodiment of the present disclosure describes that a first feature is formed on or above a second feature, this may refer to embodiments in which the first and second features are in direct contact, and may also include embodiments in which one or more additional features are formed between the first and second features, such that the first and second features are not directly in contact.

It should be noted that additional steps may be performed before, between, or after the described steps in the disclosed methods. In other embodiments of the methods, some of the steps may be replaced or omitted.

Furthermore, spatial terms such as “below,” “under,” “lower,” “above,” “over,” “higher,” and similar expressions may be used for describing the positional relationships between one or more elements or features in the figures. These spatial terms include the orientation of the device during use or operation as well as the orientations described in the drawings. When the device is rotated (e.g., 90 degrees or another orientation), the spatial adjectives used shall be interpreted according to the rotated orientation.

In the specification, the terms “approximately,” “about,” and “substantially” typically mean within 20%, or 10%, or 5%, or 3%, or 2%, or 1%, or 0.5% of a given value or range. The indicated quantity is considered an approximate value. Therefore, even when such terms are not specifically stated, their implications may be inherently included.

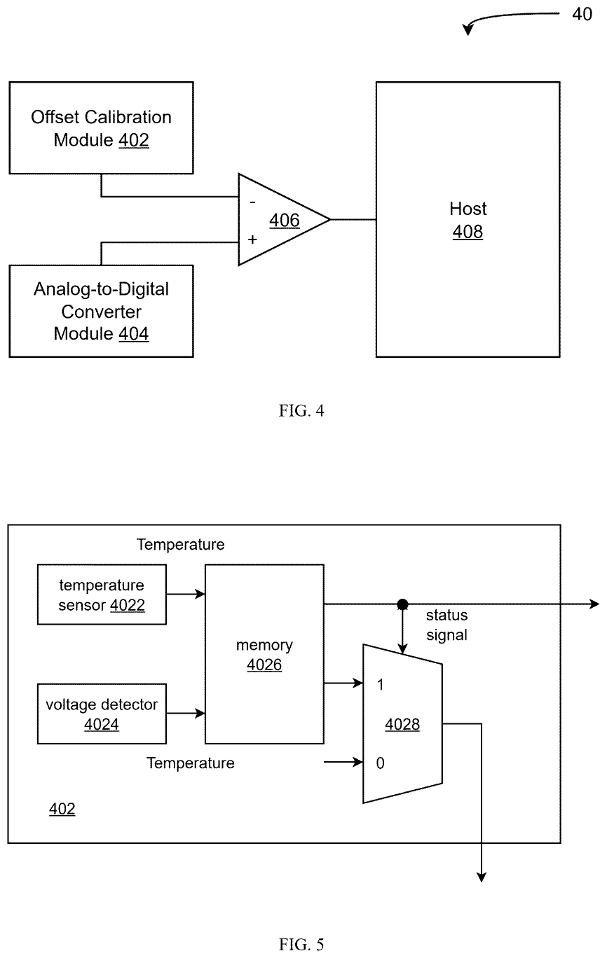

FIG. 4 is a block diagram of an electronic device according to an embodiment of the present disclosure. Referring to FIG. 4, the electronic device 40 includes an offset calibration module 402, an analog-to-digital converter (ADC) module 404, an operational amplifier 406, and a host 408. For example, the electronic device 40 may be a portable device such as a notebook computer or tablet computer, or a desktop computer. However, the present disclosure is not limited thereto.

The offset calibration module 402 is configured to measure an operating voltage and a temperature of the electronic device 40, and to determine whether the offset calibration module 402 stores, records, or writes offset error information associated with the operating voltage and the temperature.

The host 408 is electrically connected to the offset calibration module 402 and the ADC module 404 and is configured to receive a status signal from the offset calibration module 402. For example, the status signal may indicate whether the offset calibration module 402 stores the offset error information.

A negative input terminal of the operational amplifier 406 is electrically connected to the offset calibration module 402, a positive input terminal of the operational amplifier 406 is electrically connected to the ADC module 404, and an output terminal of the operational amplifier 406 is electrically connected to the host 408.

When the offset calibration module 402 stores the offset error information, the offset calibration module 402 automatically loads, reads, and outputs the offset error information to the operational amplifier 406. The ADC module 404, in response to a trigger signal, performs a normal analog-to-digital conversion and outputs a raw value to the operational amplifier 406. The operational amplifier 406 then outputs a result value (equal to the raw value minus the offset error information) to the host 408.

Based on the foregoing, the operation of the offset calibration module 402 in the embodiment of the present disclosure can be applied before the ADC module performs conversion. When reference offset error information is already available in the system, the ADC module does not need to perform an additional offset calibration procedure, thereby improving the efficiency of system operation.

In some embodiments, when the offset calibration module 402 does not store the offset error information, the analog-to-digital converter module 404 may perform an offset error calibration procedure based on the trigger signal to obtain or output the offset error information, and the offset calibration module 402 stores the offset error information.

FIG. 5 is a block diagram of an offset calibration module according to an embodiment of the present disclosure. The offset calibration module 402 in FIG. 4 is used as an example. Referring to FIG. 5, the offset calibration module 402 may include a temperature sensor 4022, a voltage detector 4024, a memory 4026, and a multiplexer 4028.

The temperature sensor 4022 is configured to measure the temperature. The voltage detector 4024 is configured to measure the operating voltage. The multiplexer 4028 is electrically connected to the operational amplifier 406. The memory 4026 is electrically connected to the temperature sensor 4022, the voltage detector 4024, the multiplexer 4028, and the host 408. The memory 4026 is configured such that: when the memory 4026 stores/has stored the offset error information, the memory 4026 outputs the offset error information to a first input terminal of the multiplexer 4028 and outputs the status signal to a select control terminal of the multiplexer 4028; and when the memory 4026 does not store the offset error information, the memory 4026 outputs the status signal to the select control terminal of the multiplexer 4028. In some embodiments, a second input terminal of the multiplexer 4028 may be maintained at 0. In such embodiments, when the memory 4026 stores the offset error information, based on the status signal, the multiplexer 4028 outputs the offset error information. When the memory 4026 does not store the offset error information, based on the status signal, the multiplexer 4028 outputs 0.

In some embodiments, the memory 4026 may be a non-volatile memory (NVM) or a register. However, the present disclosure is not limited thereto.

In some embodiments, the analog-to-digital converter module 404 may output the offset error information to the host 408, and the host 408 may output the offset error information to the offset calibration module 402. In other embodiments, the analog-to-digital converter module 404 may directly output the offset error information to the offset calibration module 402.

In some embodiments, the offset error information may include, for example, an offset error voltage value.

In some embodiments, a voltage range corresponding to the offset error information may include, for example, the operating voltage, and a temperature range corresponding to the offset error information may include, for example, the temperature.

Table 1 illustrates the corresponding relationships between the offset error information and the voltage, and between the offset error information and the temperature.

TABLE 1

| | | | | | | | | | |
|---|---|---|---|---|---|---|---|---|---|
| −10 | 0 | 10 | 20 | 30 | 40 | 50 | 60 | 70 | 80 |

| | | | | |
|---|---|---|---|---|
| 2.0 | | | | |
| 2.2 | | | | |
| 2.4 | | | | V_{OS4} |
| 2.6 | | V_{OS2} | V_{OS3} | |
| 2.8 | V_{OS1} | | | |
| 3.0 | | | | |
| 3.2 | | | | |
| 3.4 | | | | |
| 3.6 | | | | |

According to Table 1, it is assumed that the offset calibration module 402 has stored offset error information V_{OS1}, V_{OS2}, V_{OS3}, and V_{OS4}. A voltage range corresponding to V_{OS1} may be from 2.7 to 2.9, and a temperature range corresponding to V_{OS1} may be from −15 to −5. A voltage range corresponding to V_{OS2} may be from 2.5 to 2.7, and a temperature range corresponding to V_{OS2} may be from 25 to 35. A voltage range corresponding to V_{OS3} may be from 2.5 to 2.7, and a temperature range corresponding to V_{OS3} may be from 35 to 45. A voltage range corresponding to V_{OS4} may be from 2.3 to 2.5, and a temperature range corresponding to V_{OS4} may be from 55 to 65.

When the target operating voltage is 2.67 and the target temperature is 32, the offset calibration module 402 first determines whether it has stored target offset error information associated with the target operating voltage and the target temperature. Since the target operating voltage of 2.67 falls within the voltage range corresponding to V_{OS2} (2.5 to 2.7), and the target temperature falls within the temperature range corresponding to V_{OS2} (25 to 35), the offset calibration module 402 has stored the target offset error information, and V_{OS2} can be used as the target offset error information. In this case, the offset calibration module 402 outputs V_{OS2} to the operational amplifier 406, and the analog-to-digital converter module 404, in response to a trigger signal, performs a normal analog-to-digital conversion to output a raw value to the operational amplifier 406. The operational amplifier 406 then outputs a result value (i.e., the raw value minus V_{OS2}) to the host 408.

When the target operating voltage is 2.1 and the target temperature is 14, the offset calibration module 402 first determines whether it has stored target offset error information associated with the target operating voltage and the target temperature. As shown in Table 1, the offset calibration module 402 has not stored the target offset error information. In this case, the analog-to-digital converter module 404 performs an offset error calibration procedure based on the trigger signal to obtain the target offset error information, and the offset calibration module 402 stores the target offset error information (e.g., V_{OS5}, which is not shown in Table 1).

It should be noted that Table 1 is provided for illustrative purposes only and is not intended to limit the present disclosure.

In some embodiments, the host 408 may output the trigger signal to the analog-to-digital converter module 404, and the trigger signal may be responsive to the status signal. In other words, the offset calibration module 402 indirectly triggers the analog-to-digital converter module 404 to perform an operation (e.g., the normal analog-to-digital conversion or the offset error calibration procedure).

In some embodiments, when the offset calibration module 402 has stored the offset error information, the status signal may indicate a first value (e.g., 1), and the trigger signal may indicate that the analog-to-digital converter module 404 is to perform the normal analog-to-digital conversion.

In some embodiments, when the offset calibration module 402 has not stored the offset error information, the status signal may indicate a second value (e.g., 0), and the trigger signal may indicate that the analog-to-digital converter module is to perform the offset error calibration procedure.

In some embodiments, the offset calibration module 402 may output the trigger signal to the analog-to-digital converter module 404. In other words, the offset calibration module 402 directly triggers the analog-to-digital converter module 404 to perform an operation (e.g., the normal analog-to-digital conversion or the offset error calibration procedure).

In some embodiments, the analog-to-digital converter module 404 may be a sigma-delta (or delta-sigma, also known as delta modulation) analog-to-digital converter module (i.e., including a sigma-delta modulator).

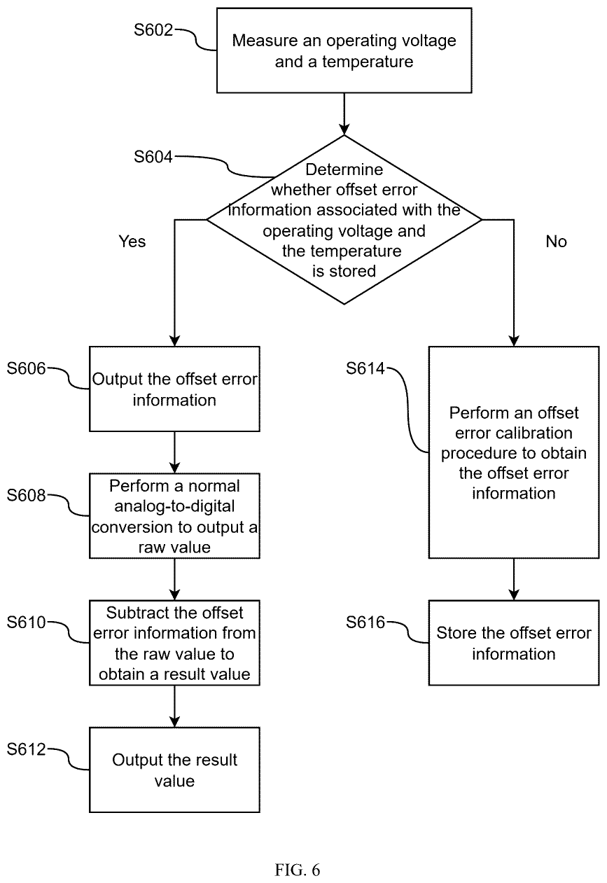

According to the above embodiments, the following offset calibration method can be obtained (e.g., summarized). FIG. 6 is a flowchart illustrating an offset calibration method according to an embodiment of the present disclosure. The offset calibration method includes the following steps:

In step S602, an operating voltage and a temperature are measured, and then step S604 is performed.

In step S604, it is determined whether an offset calibration module (e.g., offset calibration module 402) has stored offset error information associated with the operating voltage and the temperature. When the offset calibration module has stored the offset error information, step S606 is performed. When the offset calibration module has not stored the offset error information, step S614 is performed.

In step S606, the offset error information is output through the offset calibration module, and then step S608 is performed.

In step S608, a normal analog-to-digital conversion is performed through an analog-to-digital converter module (e.g., analog-to-digital converter module 404) to output a raw value, and then step S610 is performed.

In step S610, the raw value is subtracted by the offset error information to obtain a result value, and then step S612 is performed.

In step S612, the result value is output.

In step S614, an offset error calibration procedure is performed through the analog-to-digital converter module to obtain the offset error information, and then step S616 is performed.

In step S616, the offset error information is stored through the offset calibration module.

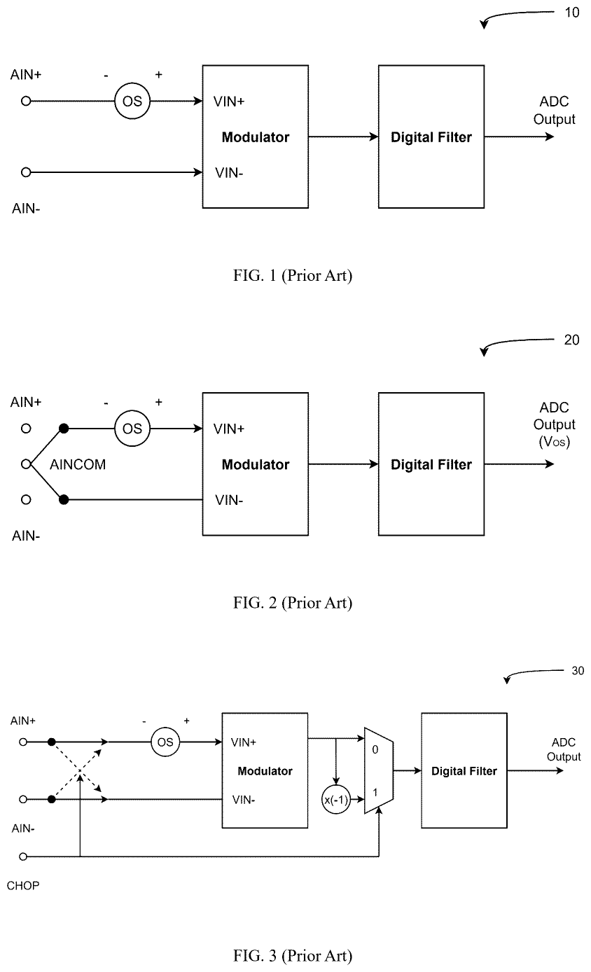

In some embodiments, the analog-to-digital converter module 404 may provide a common-mode voltage (or reference voltage). The operation in which the analog-to-digital converter module 404 performs the offset error calibration procedure to obtain the offset error information may include: the analog-to-digital converter module 404 applying the common-mode voltage to perform the offset error calibration procedure to obtain the offset error information. For example, the common-mode voltage may be provided by a common-mode voltage pin (e.g., AlNCOM in FIG. 2). The analog-to-digital converter module 404 electrically connects the common-mode voltage pin to a modulator (e.g., a positive input terminal (e.g., VIN+ in FIG. 2) and a negative input terminal (e.g., VIN− in FIG. 2) of the modulator) to obtain the offset error information. In some embodiments, the operation in which the analog-to-digital converter module 404 performs the normal analog-to-digital conversion to output the raw value may include: the analog-to-digital converter module 404 electrically connects the first input terminal and the second input terminal to the modulator to obtain and output the raw value. In some embodiments, the analog-to-digital converter module 404 may further include a digital filter, and the trigger signal may trigger the digital filter to perform an operation.

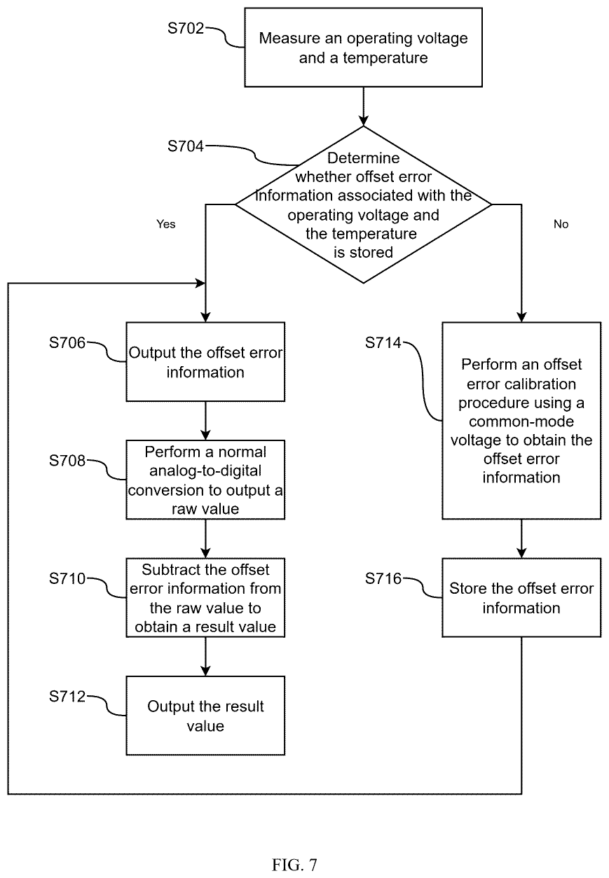

According to the above embodiments, the following offset calibration method can be obtained (e.g., summarized). FIG. 7 is a flowchart illustrating an offset calibration method according to an embodiment of the present disclosure. The offset calibration method includes the following steps:

Steps S702 to S712 correspond to steps S602 to S612 described above and are not repeated here.

In step S714, the analog-to-digital converter module applies a common-mode voltage to perform an offset error calibration procedure to obtain the offset error information, and then step S716 is performed.

In step S716, the offset error information is stored through the offset calibration module, and then step S706 is performed. Specifically, since the offset calibration module has stored or recorded the offset error information for reference, the analog-to-digital converter module only needs to perform the normal conversion.

In some embodiments, the analog-to-digital converter module 404 may provide a chopper function/mode. The operation in which the analog-to-digital converter module 404 performs the offset error calibration procedure to obtain the offset error information may include: the analog-to-digital converter module 404 performs the normal analog-to-digital conversion to obtain the raw value, applies the chopper function to perform the offset error calibration procedure to obtain the result value, and subtracts the result value from the raw value to obtain the offset error information. It should be noted that the timing of the above operations may also be that the analog-to-digital converter module 404 first applies the chopper function to perform the offset error calibration procedure to obtain the result value, and then performs the normal analog-to-digital conversion to obtain the raw value. However, the present disclosure is not limited thereto. In some embodiments, the operation in which the analog-to-digital converter module 404 performs the normal analog-to-digital conversion to output the raw value may include: the analog-to-digital converter module 404 performs the normal analog-to-digital conversion to obtain the raw value. The analog-to-digital converter module 404 does not need to apply the chopper function. In some embodiments, the analog-to-digital converter module 404 may further include a digital filter, and the trigger signal may trigger the digital filter to perform an operation.

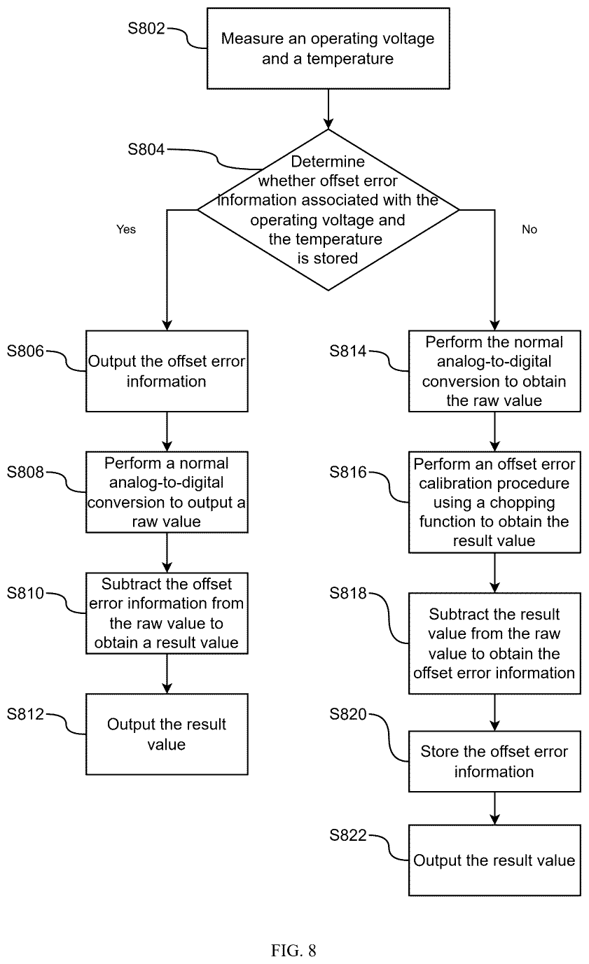

According to the above embodiments, the following offset calibration method can be obtained (e.g., summarized). FIG. 8 is a flowchart illustrating an offset calibration method according to an embodiment of the present disclosure. The offset calibration method includes the following steps:

Steps S802 to S812 correspond to steps S602 to S612 described above and are not repeated here.

In step S814, the analog-to-digital converter module performs the normal analog-to-digital conversion to obtain the raw value, and then step S816 is performed.

In step S816, the analog-to-digital converter module applies a chopper function to perform an offset error calibration procedure to obtain the result value, and then step S818 is performed.

In step S818, the raw value is subtracted by the result value to obtain the offset error information, and then step S820 is performed.

In step S820, the offset error information is stored through the offset calibration module, and then step S822 is performed.

In step S822, the result value is output.

It should be noted that the operational sequence of steps S814 to S822 is merely exemplary. For example, the order of operations in steps S814 and S816 may be reversed. Step S822 may be performed after step S816.

In summary, the electronic device and the offset calibration method disclosed herein can effectively calibrate the offset error of the ADC module.

Although the present application has been disclosed above with reference to exemplary embodiments, it is not intended to limit the present disclosure. Various modifications and alterations to the above embodiments by those skilled in the art without departing from the spirit and scope of the present disclosure shall fall within the scope of protection of the present disclosure. Therefore, the scope of protection of the present disclosure shall be defined by the claims.

What is claimed is:

1. An electronic device, comprising:
an offset calibration module configured to:
measure an operating voltage and a temperature; and
determine whether the offset calibration module stores offset error information associated with the operating voltage and the temperature;
an analog-to-digital converter module;
a host electrically connected to the offset calibration module and the analog-to-digital converter module to receive a status signal from the offset calibration module; and
an operational amplifier having a negative input terminal electrically connected to the offset calibration module, a positive input terminal electrically connected to the analog-to-digital converter module, and an output terminal electrically connected to the host,
wherein when the offset calibration module stores the offset error information, the offset calibration module outputs the offset error information to the operational amplifier, and the analog-to-digital converter module performs a normal analog-to-digital conversion based on a trigger signal to output a raw value to the operational amplifier, such that the operational amplifier outputs a result value to the host.

2. The electronic device of claim 1, wherein the offset calibration module comprises:
a temperature sensor configured to measure the temperature;
a voltage detector configured to measure the operating voltage;
a multiplexer electrically connected to the operational amplifier; and
a memory electrically connected to the temperature sensor, the voltage detector, the multiplexer, and the host to:
output the offset error information to a first input terminal of the multiplexer and output the status signal to a select control terminal of the multiplexer when the memory stores the offset error information; and
output the status signal to the select control terminal of the multiplexer when the memory does not store the offset error information.

3. The electronic device of claim 1, wherein when the offset calibration module does not store the offset error information, the analog-to-digital converter module performs an offset error calibration procedure based on the trigger signal to obtain the offset error information, and the offset calibration module stores the offset error information.

4. The electronic device of claim 3, wherein the analog-to-digital converter module provides a common-mode voltage, and the analog-to-digital converter module applies the common-mode voltage to perform the offset error calibration procedure to obtain the offset error information.

5. The electronic device of claim 3, wherein
the analog-to-digital converter module provides a chopper function, and
the analog-to-digital converter module performs the normal analog-to-digital conversion to obtain the raw value, applies the chopper function to perform the offset error calibration procedure to obtain a result value, and subtracts the result value from the raw value to obtain the offset error information.

6. The electronic device of claim 1, wherein the offset error information comprises an offset error voltage value.

7. The electronic device of claim 1, wherein a voltage range associated with the offset error information comprises the operating voltage, and a temperature range associated with the offset error information comprises the temperature.

8. The electronic device of claim 1, wherein when the offset calibration module stores the offset error information, the status signal indicates a first value, and the trigger signal indicates that the analog-to-digital converter module performs the normal analog-to-digital conversion.

9. The electronic device of claim 3, wherein when the offset calibration module does not store the offset error information, the status signal indicates a second value, and the trigger signal indicates that the analog-to-digital converter module performs the offset error calibration procedure.

10. An offset calibration method applicable to an electronic device, the electronic device comprising an offset calibration module and an analog-to-digital converter module, the method comprising:
measuring an operating voltage and a temperature;
determining whether the offset calibration module stores offset error information associated with the operating voltage and the temperature;
when the offset calibration module stores the offset error information:
outputting the offset error information via the offset calibration module;
performing a normal analog-to-digital conversion via the analog-to-digital converter module to output a raw value; and
subtracting the offset error information from the raw value to obtain a result value; and
when the offset calibration module does not store the offset error information:
performing an offset error calibration procedure via the analog-to-digital converter module to obtain the offset error information; and
storing the offset error information via the offset calibration module.
